(19) United States
(12) Patent Application Publication
(10) Pub. No.: US 2005/0161585 A1
(43) Pub. Date: Jul. 28, 2005

(54) Solid-state imaging device

(75) Inventors: Hayato Nakashima, Anpachi-gun (JP); Ryu Shimizu, Mizuho-shi (JP); Mitsuru Okigawa, Nagoya-shi (JP); Tetsuya Miwa, Yourou-gun (JP)

Correspondence Address: MCDERMOTT WILL & EMERY LLP, 600 13TH STREET, N.W., WASHINGTON, DC, 20005-3096, US

(73) Assignee: Sanyo Electric Co., Ltd.

(21) Appl. No.: 11/041,252

(22) Filed: Jan. 25, 2005

(30) Foreign Application Priority Data
Jan. 27, 2004 (JP) JP2004-017759

(51) Int. Cl. H01L 27/00

(52) U.S. Cl. 250/208.1

(57) ABSTRACT

A solid-state imaging device capable of suppressing deterioration of the image quality is provided. This solid-state imaging device comprises a substrate provided with a photodetection area, a color filter layer formed above the photodetection area and a lens formed between the substrate and the color filter layer for condensing light on the photodetection area. The lens has a substantially flat upper surface portion, and the ratio (w/t) of the width w of the substantially flat upper surface portion of the lens to the thickness t of the lens is not more than about 0.86.

### BACKGROUND OF THE INVENTION

1. Field of the Invention

The present invention relates to a solid-state imaging device, and more particularly, it relates to a solid-state imaging device comprising a lens for condensing light on a photodetection area.

2. Description of the Background Art

A solid-state imaging device comprising lenses for condensing light on photodetection areas is known in general. Such a solid-state imaging device is disclosed in “The Basis of Solid-State Imaging Devices” by Takao Ando and Hiroyoshi Komobuchi, Nihon Riko Shuppan-Kai, Dec. 5, 1999, pp. 98-99, for example. FIG. 27 is a cross sectional view showing the structure of a pixel of a conventional solid-state imaging device comprising lenses. The structure of a pixel of the conventional solid-state imaging device comprising lenses is described with reference to FIG. 27.

In the conventional solid-state imaging device, photodetection areas 102 having a photoelectric conversion function are formed on the surface of a silicon substrate 101, as shown in FIG. 27. A gate electrode 104 is formed on the silicon substrate 101 through a gate insulating film 105. An insulating film 105 having a contact hole 105a reaching the upper surface of the gate electrode 104 is formed on the gate electrode 104. Polysilicon films 106 are formed on prescribed regions of the insulating film 105. The left polysilicon film 106 is formed to fill up the contact hole 105a. A planarization film 107 having contact holes 107a reaching the upper surfaces of the polysilicon films 106 are formed on the insulating film 105 to cover the polysilicon films 106. Plugs 108 are formed in the contact holes 107a of the planarization film 107 to be connected to the polysilicon films 106.

A color filter layer 110 is formed on the planarization film 107 through an insulating film 109. A plurality of upwardly convex hemispheric lenses 111 consisting of insulating films are formed on the color filter layer 110. The conventional solid-state imaging device condenses incident light on the photodetection areas 102 through the lenses 111 formed on the color filter layer 110.

In the aforementioned conventional solid-state imaging device, however, the lenses 111 are formed on the color filter layer 110, to result in a large distance between the lenses 111 and the photodetection areas 102. Therefore, oblique incident light may disadvantageously be incident not upon a prescribed photodetection area 102 corresponding to a prescribed lens 111 but upon another photodetection area 102 adjacent to the prescribed photodetection area 102. This leads to reduction of sensitivity or cross talk, disadvantageously deteriorating the image quality.

### SUMMARY OF THE INVENTION

The present invention has been proposed in order to solve the aforementioned problem, and an object of the present invention is to provide a solid-state imaging device capable of suppressing deterioration of the image quality.

In order to attain the aforementioned object, a solid-state imaging device according to an aspect of the present invention comprises a substrate provided with a photodetection area, a color filter layer formed above the photodetection area and a lens formed between the substrate and the color filter layer for condensing light on the photodetection area, while the lens has a substantially flat upper surface portion, and the ratio (w/t) of the width w of the substantially flat upper surface portion of the lens to the thickness t of the lens is not more than about 0.86.

In the solid-state imaging device according to this aspect, as hereinabove described, the lens having the substantially flat upper surface portion is so formed between the substrate and the color filter layer that the distance between the lens and the photodetection area can be reduced. Further, the ratio (w/t) of the width w of the substantially flat upper surface portion of the lens to the thickness t of the lens is so set to not more than about 0.86 that the width w of the substantially flat upper surface portion of the lens can be reduced assuming that the thickness t of the lens is constant, whereby the region of the substantially flat upper surface portion not contributing to condensation of light can be reduced. Thus, the condensing efficiency can be so improved that reduction of sensitivity resulting from a failure in incidence of light upon a prescribed photodetection area or cross talk resulting from incidence of light upon another photodetection area adjacent to the prescribed photodetection area can be suppressed. Consequently, deterioration of the image quality can be suppressed.

In the solid-state imaging device according to the aforementioned aspect, the width of the lens is preferably not more than about 2.7 μm. According to this structure, the width w of the substantially flat upper surface portion of the lens is also reduced following reduction of the width of the lens, whereby the ratio (w/t) of the width w of the substantially flat upper surface portion of the lens to the thickness t of the lens can be easily set to not more than about 0.86. Thus, the condensing efficiency can be easily improved.

In the solid-state imaging device according to the aforementioned aspect, the ratio (w/t) of the width w of the substantially flat upper surface portion of the lens to the thickness t of the lens is preferably not more than about 0.65, and the width of the lens is preferably not more than about 3 μm. According to this structure, the region of the substantially flat upper surface portion not contributing to condensation of light can be easily reduced in the lens having the width of not more than about 3 μm, whereby the condensing efficiency can be easily improved.

In the solid-state imaging device according to the aforementioned aspect, the lens preferably includes a plurality of layers. According to this structure, the condensing efficiency can be easily improved in the lens including the plurality of layers.

The solid-state imaging device according to the aforementioned aspect preferably further comprises a first metal wire formed on a region other than a region of the substrate provided with the photodetection area and a second metal wire formed on the first metal wire through a first insulating film, and the lens preferably includes a second insulating film consisting of the same layer as at least the first insulating film. According to this structure, no insulating film may be separately formed for insulating the first and second metal wires from each other, whereby a manufacturing process for the solid-state imaging device can be simplified.

In the aforementioned structure having the second metal wire formed on the first metal wire through the first insulating film with the lens including the second insulating film consisting of the same layer as the first insulating film, the first metal wire preferably has a function of supplying an external signal to a pixel, and the second metal wire preferably has a function of supplying the external signal to the first metal wire. According to this structure, the manufacturing process for the solid-state imaging device including the first metal wire for supplying the external signal to the pixel and the second metal wire for supplying the external signal to the first metal wire can be easily simplified.

In the aforementioned structure having the second metal wire formed on the first metal wire through the first insulating film with the lens including the second insulating film consisting of the same layer as the first insulating film, the second insulating film constituting the lens preferably has an upwardly convex projecting portion. According to this structure, the lens including the second insulating film can be easily shaped to include the upwardly convex projecting portion.

In the aforementioned structure having the second metal wire formed on the first metal wire through the first insulating film with the lens including the second insulating film consisting of the same layer as the first insulating film, the first insulating film and the second insulating film preferably consist of SiN films. According to this structure, the first and second metal wires can be easily insulated from each other through the first insulating film (SiN film), and the second insulating film (SiN film) can easily function as the lens.

In the aforementioned structure having the second metal wire formed on the first metal wire through the first insulating film with the lens including the second insulating film consisting of the same layer as the first insulating film, the solid-state imaging device preferably further comprises a third insulating film arranged downward beyond the upper end of the first metal wire and a fourth insulating film, formed under the second insulating film constituting the lens, consisting of the same layer as the third insulating film and constituting the lens along with the second insulating film, and the fourth insulating film is preferably arranged downward beyond the upper end of the first metal wire. According to this structure, no insulating film may be separately formed for insulating the first metal wire from a prescribed layer formed under the first metal wire, whereby the manufacturing process for the solid-state imaging device can be simplified when forming the lens constituted of the second and fourth insulating films.

In the aforementioned structure having the third insulating film arranged downward beyond the upper end of the first metal wire with the lens including the fourth insulating film consisting of the same layer as the third insulating film, the fourth insulating film constituting the lens preferably has a substantially flat surface, and the second insulating film is preferably formed on the substantially flat surface of the fourth insulating film. According to this structure, the lens including the fourth insulating film having the substantially flat surface can be easily formed.

In the aforementioned structure having the third insulating film arranged downward beyond the upper end of the first metal wire with the lens including the fourth insulating film consisting of the same layer as the third insulating film, the third insulating film and the fourth insulating film preferably consist of SiN films. According to this structure, the first metal wire can be easily insulated from a prescribed layer formed under the first metal wire through the third insulating film (SiN film), and the fourth insulating film (SiN film) can easily function as the lens.

In the aforementioned structure having the third insulating film arranged downward beyond the upper end of the first metal wire with the lens including the fourth insulating film consisting of the same layer as the third insulating film, the second insulating film and the fourth insulating film constituting the lens preferably consist of materials having substantially identical refractive indices. According to this structure, incident light can be inhibited from reflection resulting from difference between the refractive indices on the interface between the second and fourth insulating films. Thus, reduction of the condensing efficiency can be suppressed in the lens constituted of the second and fourth insulating films.

In the aforementioned structure having the third insulating film arranged downward beyond the upper end of the first metal wire with the lens including the fourth insulating film consisting of the same layer as the third insulating film, at least either the second insulating film or the fourth insulating film preferably consists of a material containing hydrogen. According to this structure, hydrogen is so supplied to the surface of the substrate in formation of the second or fourth insulating film that dangling bonds (unpaired bonds) on the surface of the substrate can be terminated by the supplied hydrogen. Thus, the number of dangling bonds can be so reduced on the substrate that the number of surface state resulting from dangling bonds can also be reduced. Consequently, a dark current resulting from surface state can be reduced.

In this case, both of the second insulating film and the fourth insulating film preferably consist of materials containing hydrogen. According to this structure, hydrogen is supplied to the surface of the substrate in formation of both of the second and fourth insulating films, whereby dangling bonds (unpaired bonds) on the surface of the substrate can be terminated by the hydrogen supplied in formation of both of the second and fourth insulating films.

In the aforementioned structure having the second metal wire formed on the first metal wire through the first insulating film with the lens including the second insulating film consisting of the same layer as the first insulating film, the solid-state imaging device preferably further comprises a fifth insulating film formed on the second metal wire and a sixth insulating film, formed on the second insulating film constituting the lens, consisting of the same layer as the fifth insulating film and constituting the lens along with the second insulating film. According to this structure, the sixth insulating film constituting the lens can be so utilized as a protective film for the second metal wire that no protective film for the second metal wire may be separately formed. Thus, a step of forming the protective film for the second metal wire can be so omitted that the manufacturing process for the solid-state imaging device can be simplified when forming the lens constituted of the second and sixth insulating films.

In the aforementioned structure having the fifth insulating film formed on the second metal wire with the lens including the sixth insulating film consisting of the same layer as the fifth insulating film, the second insulating film constituting the lens preferably includes a plurality of upwardly convex projecting portions formed at a prescribed interval, and the sixth insulating film constituting the lens is preferably formed to fill up a flat portion between adjacent projecting portions of the second insulating film. According to this structure, the flat portion not contributing to condensation of light is so eliminated from between the adjacent projecting portions of the second insulating film that the condensing efficiency can be easily more improved.

In the aforementioned structure having the sixth insulating film formed to fill up the flat portion between the adjacent projecting portions of the second insulating film, a region of the sixth insulating film constituting the lens corresponding to the flat portion between the adjacent projecting portions of the second insulating film is preferably formed to include no flat portion. According to this structure, the region of the sixth insulating film corresponding to the flat portion between the adjacent projecting portions of the second insulating film includes no flat portion not contributing to condensation of light, whereby the condensing efficiency can be easily more improved.

In the aforementioned structure having the fifth insulating film formed on the second metal wire with the lens including the sixth insulating film consisting of the same layer as the fifth insulating film, the sixth insulating film constituting the lens is preferably formed to be upwardly convex, and preferably has a substantially flat upper surface portion. According to this structure, the lens including the sixth insulating film having the substantially flat upper surface portion can be easily formed.

In the aforementioned structure having the fifth insulating film formed on the second metal wire with the lens including the sixth insulating film consisting of the same layer as the fifth insulating film, the fifth insulating film and the sixth insulating film preferably consist of SiN films. According to this structure, the fifth insulating film (SiN film) can easily function as a protective film for the second metal wire, and the sixth insulating film (SiN film) can easily function as the lens.

In the aforementioned structure having the fifth insulating film formed on the second metal wire with the lens including the sixth insulating film consisting of the same layer as the fifth insulating film, the second insulating film and the sixth insulating film constituting the lens preferably consist of materials having substantially identical refractive indices. According to this structure, incident light can be inhibited from reflection resulting from difference between the refractive indices on the interface between the second and sixth insulating films. Thus, reduction of the condensing efficiency can be suppressed in the lens constituted of the second and sixth insulating films.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a block diagram showing the overall structure of a solid-state imaging device according to a first embodiment of the present invention;

FIG. 2 is a pixel structure of a pixel of an image area of the solid-state imaging device according to the first embodiment shown in FIG. 1;

FIG. 3 is a cross sectional view showing the structures of the pixel and a wire forming region of the solid-state imaging device according to the first embodiment shown in FIG. 1;

FIG. 4 is a graph showing results of a simulation of the relation between the ratios of the widths of substantially flat upper surface portions of lenses to the thicknesses of the lenses and condensing efficiencys;

FIGS. 5 to 8 are cross sectional views for illustrating a manufacturing process for the solid-state imaging device according to the first embodiment shown in FIG. 1;

FIGS. 9 and 10 are model diagrams showing a state of termination of dangling bonds on the surface of a substrate;

FIGS. 11 to 17 are cross sectional views for illustrating the manufacturing process for the solid-state imaging device according to the first embodiment shown in FIG. 1;

FIG. 18 is a cross sectional view for illustrating a manufacturing process for a solid-state imaging device according to a second embodiment of the present invention;

FIG. 19 is a cross sectional view showing the structures of a pixel and a wire forming region of a solid-state imaging device according to a third embodiment of the present invention;

FIGS. 20 to 26 are cross sectional views for illustrating a manufacturing process for the solid-state imaging device according to the third embodiment shown in FIG. 19; and

FIG. 27 is a cross sectional view showing the structure of a pixel of a conventional solid-state imaging device comprising lenses.

### DESCRIPTION OF THE PREFERRED EMBODIMENTS

### First Embodiment

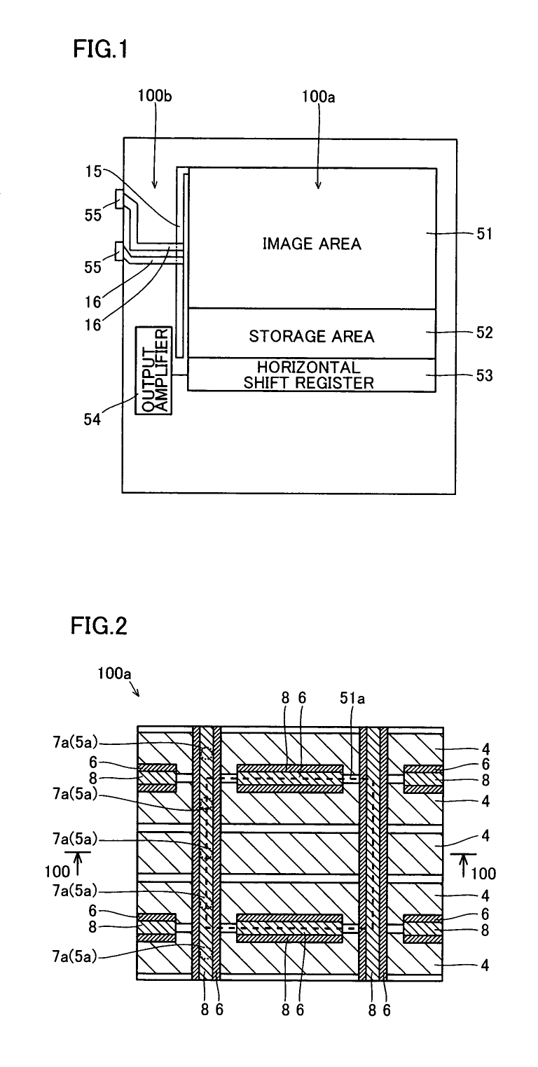

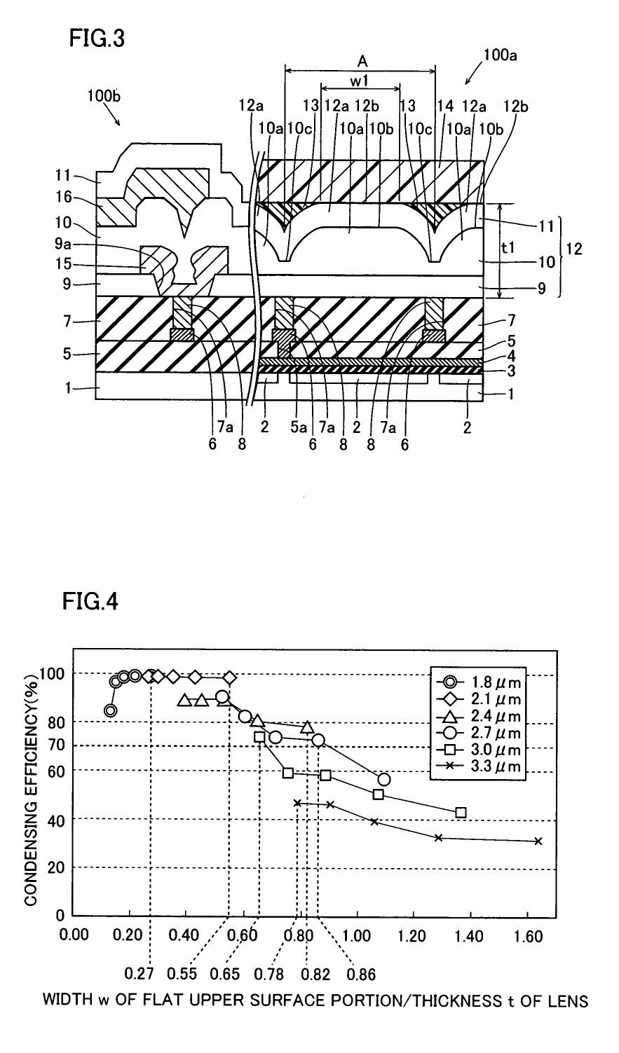

The structure of a solid-state imaging device according to a first embodiment of the present invention is described with reference to FIGS. 1 to 3. FIG. 3 is a cross sectional view of a pixel 100a of the solid-state imaging device taken along the line 100-100 in FIG. 2.

The solid-state imaging device according to the first embodiment comprises an image area 51, a storage area 52, a horizontal shift register 53, an output amplifier 54 and extension pads 55, as shown in FIG. 1. The image area 51 has a function of storing electrons generated by photoelectric conversion and transferring the same to the storage area 52. The storage area 52 has a function of storing the electrons received from the image area 51 and transferring the same to the horizontal shift register 53. The horizontal shift register 53 has a function of sequentially transferring the electrons received from the storage area 52 to the output amplifier 54. The output amplifier 54 has a function of outputting the electrons received from the horizontal shift register 53. The extension pads 55 are supplied with external signals.

The pixel 100a and a wire forming region 100b of the image area 51 of the solid-state imaging device according to the first embodiment have sectional structures shown in FIG. 3. The sectional structure of the pixel 100a of the image area 51 is now described with reference to FIGS. 2 and 3. Photodetection areas 2 having a photoelectric conversion function are formed on a surface portion of a silicon substrate 1 located on the pixel 100a. The silicon substrate 1 is an example of the “substrate” in the present invention. Gate electrodes 4 consisting of polysilicon films having a thickness of about 65 nm are formed on the portion of the silicon substrate 1 located on the pixel 100a through a gate insulating film 3 of SiO₂ having a thickness of about 30 nm. An insulating film 5, consisting of an SiO₂ film having a thickness of about 635 nm, having contact holes 5a reaching the upper surfaces of the gate electrodes 4 is formed to cover the gate electrodes 4. This insulating film 5 has a refractive index of about 1.46. Polysilicon films 6 having a thickness of about 200 nm are formed on prescribed regions of the insulating film 5. These polysilicon films 6 are formed to fill up the contact holes 5a. As shown in FIG. 2, the polysilicon films 6 located on the pixel 100a are arranged to enclose pixels 51a. While FIG. 2 illustrates only one pixel 51a, a plurality of such pixels 51a are arranged in the form of a matrix in practice. As shown in FIG. 3, a planarization film 7, consisting of an SiO₂ film having a thickness of about 815 nm, having contact holes 7a reaching the upper surfaces of the polysilicon films 6 is formed on the insulating film 5 to cover the polysilicon films 6. This planarization film 7 has a refractive index of about 1.46. Plugs 8 of tungsten are embedded in the contact holes 7a of the planarization film 7 to be connected to the polysilicon films 6.

According to the first embodiment, an insulating film 9 of SiN having a thickness of about 400 nm is formed on the planarization film 7 in the pixel firming region 100a, as shown in FIG. 3. The portion of the insulating film 9 located on the pixel 100a is an example of the “fourth insulating film” in the present invention. Another insulating film 10 of SiN having a thickness of about 800 nm is formed on the insulating film 9. The portion of the insulating film 10 located on the pixel 10a is an example of the “second insulating film” in the present invention. The insulating film 10 includes upwardly convex projecting portions 10a having substantially flat upper surface portions 10b. The plurality of projecting portions 10a are formed at prescribed intervals, while flat portions 10c are formed between adjacent ones of the projecting portions 10a. Still another insulating film 11 of SiN having a thickness of about 500 nm is formed on the insulating film 10 to fill up the flat portions 10c between the adjacent projecting portions 10a. The portion of the insulating film 11 located on the pixel 100a is an example of the “sixth insulating film” in the present invention. The insulating films 9, 10 and 11 of the pixel 100a constitute a lens 12 for condensing light on the photodetection areas 2. This lens 12 has a plurality of projecting portions 12a including substantially flat upper surface portions 12b having a width w1 of about 1.2 μm, and has a thickness t1 of about 1.7 μm. The lens 12 also has a width (pixel size) A of about 2.7 μm. The insulating films 9, 10 and 11 constituting the lens 12 have the same refractive index of about 2.05.

In the pixel 100a, a resin layer 13 of acrylic resin is formed on the lens 12 to fill up clearances between adjacent ones of the projecting portions 12a. A color filter layer 14 having a thickness of about 0.8 μm is formed on the resin layer 13 to be in contact with the substantially flat upper surface portions 12b of the lens 12.

The sectional structure of the wire forming region 100b is now described with reference to FIG. 3. In the wire forming region 100b, an insulating film 5 is formed on the surface of the silicon substrate 1. A polysilicon film 6 is formed on the insulating film 5 of the wire forming region 100b. A planarization film 7 is formed to cover the insulating film 5 and the polysilicon film 6 of the wire forming region 100b. A contact hole 7a reaching the polysilicon film 6 is formed in this planarization film 7. A plug 8 of tungsten is embedded in the contact hole 7a.

According to the first embodiment, an insulating film 9 consisting of the same layer as the insulating film 9 provided on the pixel 100a is formed on the planarization film 7 of the wire forming region 100b. The portion of the insulating film 9 located on the wire forming region 100b is an example of the “third insulating film” in the present invention. The insulating film 9 of the wire forming region 100b has a contact hole 9a. A metal wire 15 is formed to be connected to the plug 8 in the contact hole 9a, so that ends thereof extend on the insulating film 9. This metal wire 15 is an example of the “first metal wire” in the present invention. The metal wire 15 consists of a lower Al layer having a thickness of about 500 nm and an upper TiN layer having a thickness of about 20 nm. The upper TiN layer constituting the metal wire 15 functions as an antireflection film. The metal wire 15 has a function of supplying external signals to the gate electrodes 4 through the plug 8 and the polysilicon film 6.

According to the first embodiment, another insulating film 10 of the same layer as the insulating film 10 of the pixel 100a is formed to cover the insulating film 9 and the metal wire 15. The portion of the insulating film 10 located on the wire forming region 100b is an example of the “first insulating film” in the present invention. A metal wire 16 consisting of a lower Al layer having a thickness of about 500 nm and an upper TiN layer having a thickness of about 20 nm is formed on a prescribed region of the insulating film 10, as shown in FIGS. 1 and 3. This metal wire 16 is an example of the “second metal wire” in the present invention. The upper TiN layer constituting the metal wire 16 functions as an antireflection film. The metal wire 16 also has a function of supplying the external signals supplied to the extension pads 55 (see FIG. 1) to the metal wire 15. The metal wires 15 and 16 are connected with each other through a contact hole (not shown) provided in the insulating film 10. Still another insulating film 11 of the same layer as the insulating film 11 of the pixel 100a is formed to cover the insulating film 10 and the metal wire 16. The portion of the insulating film 11 located on the wire forming region 100b is an example of the “fifth insulating film” in the present invention. The insulating film 11 of the wire forming region 100b functions as a protective film for the metal wire 16.

The relation between ratios of widths w of substantially flat upper surface portions of lenses to thicknesses t of the lenses is now described with reference to FIG. 4. Referring to FIG. 4, the axis of ordinates shows condensing efficiencys (%), and the axis of abscissas shows the ratios of the widths w of the substantially flat upper surface portions of the lenses to the thicknesses t of the lenses. Simulation software employed for forming this graph is a three-dimensional optical simulator TOCCATA, Ver. 4.3.0 (by Link Research Corporation). A simulation was made with parameters of the widths w (0.30 μm, 0.60 μm, 0.90 μm, 1.20 μm (w1 in the first embodiment), 1.50 μm and 1.80 μm) of the substantially flat upper surface portions of the lenses and the thicknesses t (1.10 μm, 1.40 μm, 1.70 μm (t1 in the first embodiment), 2.00 μm and 2.30 μm) of the lenses. A photodetection region for each pixel was divided into nine sections for calculating the ratio of light condensed on the three central sections of the pixel most efficiently performing photoelectric conversion as the condensing efficiency. It was assumed that light was perpendicularly incident upon each substrate. When the pixel sizes (widths of the lenses) are 1.8 μm, 2.1 μm, 2.4 μm, 2.7 μm (A in the first embodiment), 3 μm and 3.3 μm, the widths w of the substantially flat upper surface portions of the lenses are 0.30 μm, 0.60 μm, 0.90 μm, 1.20 μm, 1.50 μm and 1.80 μm respectively.

As shown in FIG. 4, it has been proved that the ratio w (width of substantially flat upper surface portion)/t (thickness of lens) is not more than 0.27 and the condensing efficiency is extremely increased to at least 80% when the pixel size (width of lens) is 1.8 μm. It has also been proved that the ratio w/t is not more than 0.55 and the condensing efficiency is extremely increased to at least 80% when the pixel size (width of lens) is 2.1 μm. It has further been proved that the ratio w/t is not more than 0.82 and the condensing efficiency is increased to at least 70% when the pixel size (width of lens) is 2.4 μm. It has further been proved that the condensing efficiency is increased to at least 70% if the ratio w/t is not more than 0.86 while the condensing efficiency is reduced below 70% if the ratio w/t exceeds 0.86 when the pixel size (width of lens) is 2.7 μm. It has further been proved that the condensing efficiency is increased to at least 70% if the ratio w/t is not more than 0.65 while the condensing efficiency is reduced below 70% if the ratio w/t exceeds 0.65 when the pixel size (width of lens) is 3 μm. It has further been proved that the ratio w/t is at least 0.78 and the condensing efficiency is reduced below 70% when the pixel size (width of lens) is 3.3 μm.

It has been proved from the aforementioned simulation results that a high condensing efficiency of at least 70% can be obtained if the ratio w (width of substantially flat upper surface portion)/t (thickness of lens) is not more than 0.86 when the width of the lens (pixel size) is not more than 2.7 μm.

According to the first embodiment, the pixel size (the width A of the lens 12) is about 2.7 μm and the ratio w/t (w1/t1=about 1.2 μm/about 1.7 μm) is about 0.71, and hence the condensing efficiency is conceivably increased to at least 70%.

According to the first embodiment, as hereinabove described, the lens 12 having the substantially flat upper surface portions 12b is so formed between the silicon substrate 1 and the color filter layer 14 that the distance between the lens 12 and the photodetection areas 2 can be reduced. Further, the ratio (w1/t1) of the width w1 (about 1.2 μm) of the substantially flat upper surface portions 12b of the lens 12 to the thickness t1 (about 1.7 μm) of the lens 12 is so set to about 0.86 that the regions of the substantially flat upper surface portions 12b not contributing to condensation of light can be reduced. Thus, the condensing efficiency can be so improved as to suppress reduction of sensitivity resulting from a failure in incidence of light upon a prescribed photodetection area 2 or cross talk resulting from incidence of light upon another photodetection area 2 adjacent to the prescribed photodetection area 2. Consequently, deterioration of the image quality can be suppressed.

According to the first embodiment, further, the insulating film 10 consisting of the same layer as the insulating film 10 constituting the lens 12 of the pixel 100a is so formed between the metal wires 15 and 16 of the wire forming region 100b that no insulating film may be separately formed for insulating the metal wires 15 and 16 from each other. In addition, the insulating film 9 consisting of the same layer as the insulating film 9 constituting the lens 12 of the pixel 100a is so formed between the metal wire 15 of the wire forming region 100b and the insulating film 7 having the plug 8 embedded therein that no insulating film may be separately formed for insulating the metal wire 15 and the plug 8 from each other. Further, the insulating film 11 consisting of the same layer as the insulating film 11 constituting the lens 12 of the pixel 100a is so formed on the metal wire 16 of the wire forming region 100b that no protective film for the metal wire 16 may be separately formed. Thus, the insulating films 9, 10 and 11 of the wire forming region 100b are so formed by the same layers as the insulating films 9, 10 and 11 constituting the lens 12 of the pixel 100a respectively that no insulating films may be separately formed on the wire forming region 100b, whereby a manufacturing process for the solid-state imaging device can be simplified.

According to the first embodiment, further, the insulating films 9, 10 and 11 constituting the lens 12 are so formed by SiN films having the same refractive indices (about 2.05) that incident light can be inhibited from reflection resulting from difference between the refractive indices on the interfaces between the insulating films 9, 10 and 11. Thus, reduction of the condensing efficiency can be suppressed in the lens 12 formed by the three insulating films 9, 10 and 11.

According to the first embodiment, in addition, the insulating film 11 is so formed as to fill up the flat portions 10c between the adjacent projecting portions 10a of the insulating film 10 constituting the lens 12 that the flat portions 10c not contributing to condensation of light disappear from between the projecting portions 10a of the insulating film 10, whereby the condensing efficiency can be further improved.

The manufacturing process for the solid-state imaging device according to the first embodiment is now described with reference to FIGS. 3 and 5 to 17.

First, the gate electrodes 4 of polysilicon having the thickness of about 65 nm are formed on the portion of the silicon substrate 1 formed with the photodetection areas 2 located on the pixel 100a through the gate insulating film 3 of SiO₂ having the thickness of about 30 nm, as shown in FIG. 5. Thereafter the insulating films 5 of SiO₂ having the thickness of about 635 nm are formed on both of the pixel 100a and the wire forming region 100b. Thereafter the contact holes 5a reaching the upper surfaces of the gate electrodes 4 are formed in the insulating film 5 of the pixel 100a. The polysilicon films 6 having the thickness of about 200 nm are formed on the prescribed regions of the insulating films 5. The polysilicon films 6 of the pixel 100a are formed to fill up the contact holes 5a.

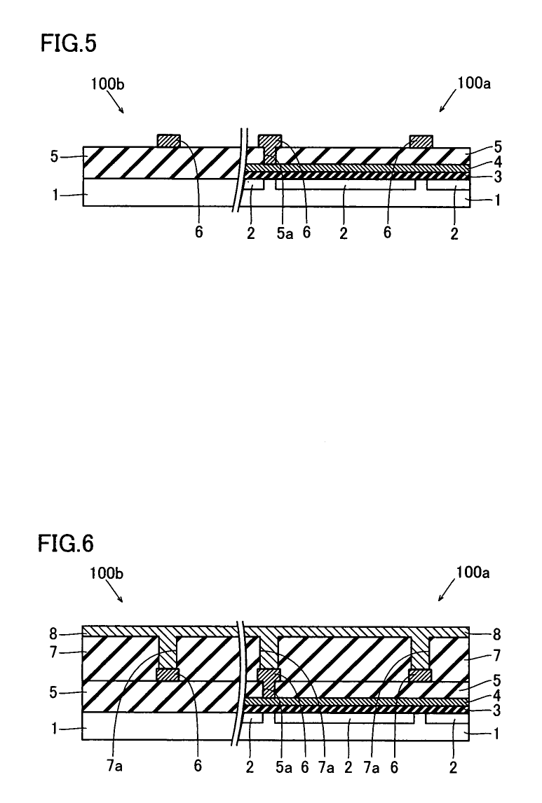

As shown in FIG. 6, the planarization film 7 of SiO₂ having the thickness of about 815 nm is formed on both insulating films 5 of the pixel 100a and the wire forming region 100b, followed by formation of the contact holes 7a reaching the upper surfaces of the polysilicon films 6 in the planarization film 7. Thereafter the plugs 8 are formed in the planarization film 7 provided on both of the pixel 100a and the wire forming region 100b, to fill up the contact holes 7a.

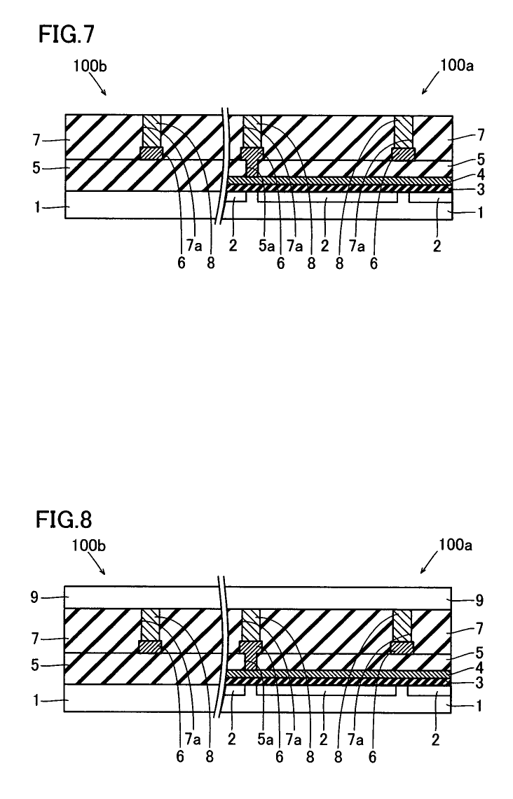

As shown in FIG. 7, unnecessary portions of the plugs 8 located on the upper surface of the planarization film 7 are removed by CMP (Chemical Mechanical Polishing), while flattening the upper surface of the planarization film 7.

As shown in FIG. 8, the insulating films 9 of SiN having the thickness of about 400 nm are formed on the planarization film 7 provided on both of the pixel 100a and the wire forming region 100b by plasma CVD.

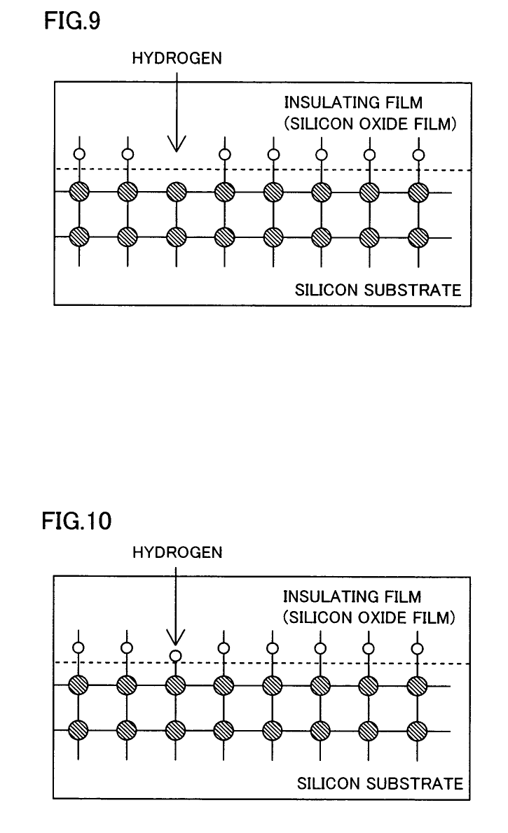

According to the first embodiment, hydrogen is supplied to the surface of the silicon substrate 1 in formation of the insulating films 9 by plasma CVD, as shown in FIG. 9. As shown in FIG. 10, therefore, dangling bonds (unpaired bonds) can be terminated with the supplied hydrogen on the surface of the silicon substrate 1. Thus, the number of the dangling bonds can be so reduced on the silicon substrate 1 as to reduce the number of surface state resulting from the dangling bonds. Therefore, a dark current resulting from surface state can be reduced.

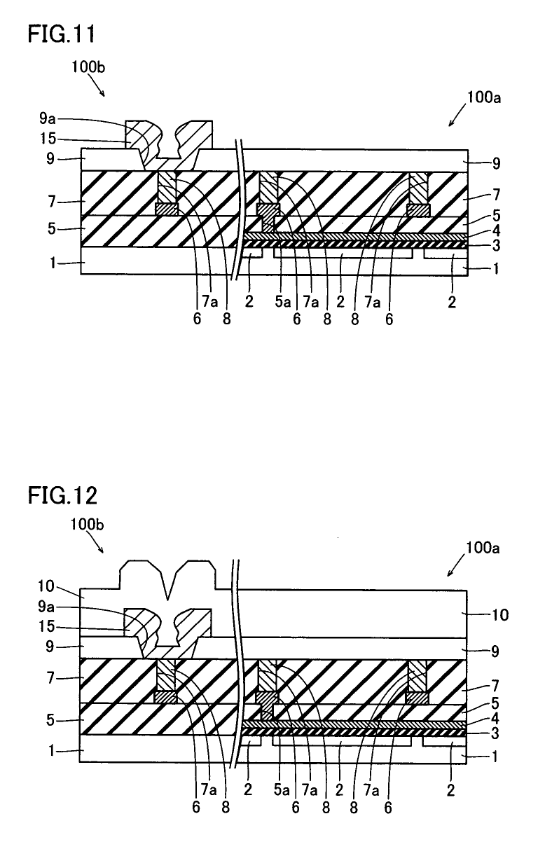

As shown in FIG. 11, the contact hole 9a reaching the upper surface of the plug 8 is formed in the insulating film 9 of the wire forming region 100b with CF₄ gas, Ar gas and O₂ gas through an oxide etching system. Thereafter the metal wire 15 consisting of the lower Al layer having the thickness of about 500 nm and the upper TiN layer having the thickness of about 20 nm is formed in the contact hole 9a to be connected to the plug 8 so that the ends thereof extend on the insulating film 9.

As shown in FIG. 12, the insulating films 10 of SiN having the thickness of about 800 nm are formed by plasma CVD to cover the insulating films 9 of the pixel 100a and the wire forming region 100b and the metal wire 15.

At this time, hydrogen is so supplied to the surface of the silicon substrate 1 according to the first embodiment that dangling bonds (unpaired-bonds) can be terminated with the supplied hydrogen on the surface of the silicon substrate 1 as shown in FIG. 10.

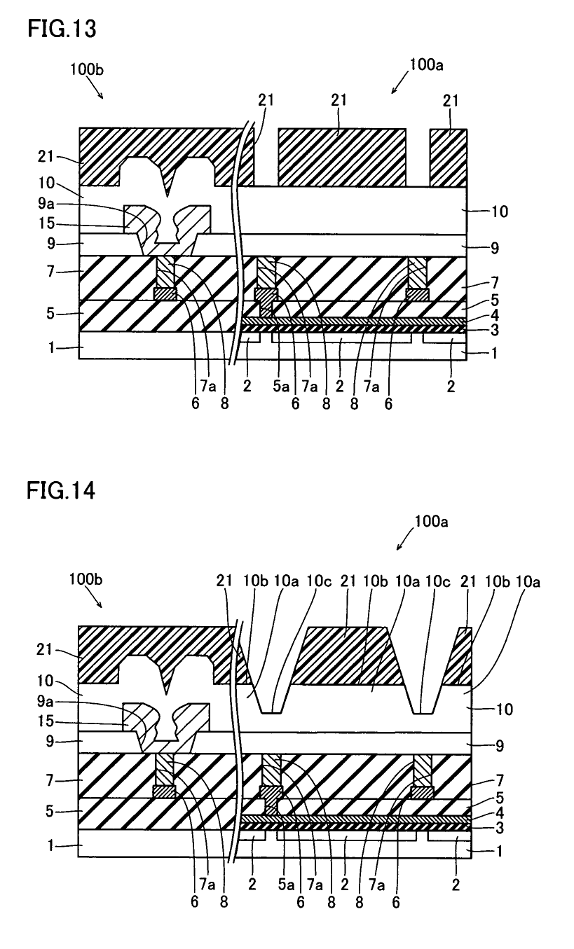

As shown in FIG. 13, resist films 21 are formed on prescribed regions of the insulating films 10 of the pixel 100a and the wire forming region 100b by photolithography.

As shown in FIG. 14, the resist films 21 are employed as masks for dry-etching the insulating film 10 of the pixel 100a up to a prescribed depth. Thus, the upwardly convex projecting portions 10a having the substantially flat upper surface portions 10b are formed on the insulating film 10 of the pixel 100a. The plurality of projecting portions 10a are formed at the prescribed intervals, along with formation of the flat portions 10c between the adjacent projecting portions 10a. Thereafter the resist films 21 are removed.

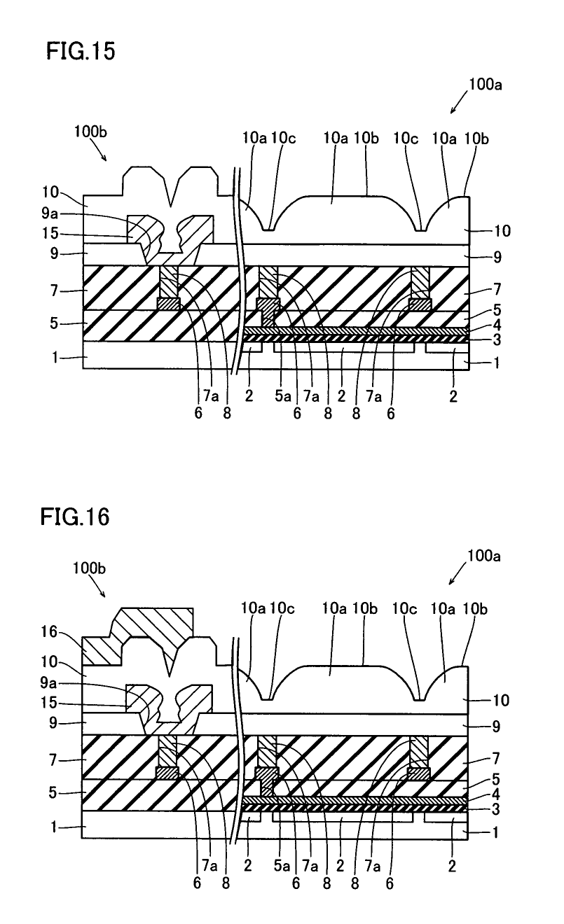

As shown in FIG. 15, ion streaming is performed for applying inert gas ions to the projecting portions 10a of the insulating film 10 of the pixel 100a through an ion streaming etching system (by Tokyo Ohka Kogyo Co., Ltd.). Thus, corners of the projecting portions 10a of the insulating film 10 are rounded, while scattered atoms and molecules are embedded in the flat portions 10c between the adjacent projecting portions 10b.

As shown in FIG. 16, a contact hole (not shown) reaching the upper surface of the metal wire 15 is formed in the insulating film 10 of the wire forming region 100b, and the metal wire 16 consisting of the lower Al layer having the thickness of about 500 nm and the upper TiN layer having the thickness of about 20 nm is thereafter formed on the prescribed region of the insulating film 10 to fill up the contact hole.

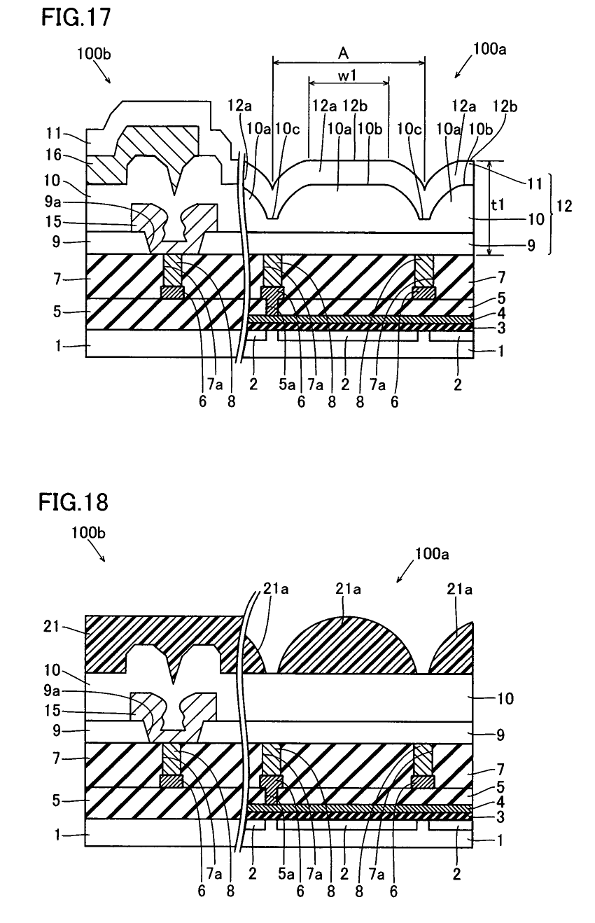

As shown in FIG. 17, the insulating films 11 of SiN having the thickness of about 500 nm are formed to cover the insulating films 10 of the pixel 100a and the wire forming region 100b and the metal wire 16 while filling up the flat portions 10c between the adjacent projecting portions 10a of the insulating film 10 of the pixel 100a. Thus formed is the lens 12 having a three-layer structure consisting of the insulating films 9, 10 and 11. This lens 12 is formed to include the plurality of projecting portions 12a, and to have the thickness t1 of about 1.7 μm. Further, the lens 12 is formed to have the width A of about 2.7 μm, and to include the substantially flat upper portions 12b having the width w1 of about 1.2 μm.

Thereafter the resin layer 13 of acrylic resin is formed on the lens 12 of the pixel 100a to fill up the clearances between the adjacent projecting portions 12a, as shown in FIG. 3. The color filter layer 14 having the thickness of about 0.8 μm is formed on the resin layer 13 to be in contact with the substantially flat upper surface portions 12b of the lens 12. Thus, the solid-state imaging device according to the first embodiment is formed.

### Second Embodiment

Referring to FIG. 18, a solid-state imaging device according to a second embodiment of the present invention is described with reference to a case of forming a lens 12 by resist flowing, dissimilarly to the aforementioned first embodiment. The solid-state imaging device according to the second embodiment has a sectional structure similar to that of the solid-state imaging device according to the first embodiment shown in FIG. 3.

In a manufacturing process for the solid-state imaging device according to the second embodiment, insulating films 10 of a pixel 100a and a wire forming region 100b are formed through a process similar to that of the first embodiment shown in FIGS. 5 to 13, followed by formation of resist films 21 on prescribed regions of the insulating films 10.

Then, heat treatment is performed through a hot plate for improving flowability of the resist films 21. Thus, upwardly convex hemispheric resist films 21a are formed due to surface tension, as shown in FIG. 18. Thereafter the resist films 21a and the insulating film 10 of the pixel 100a are simultaneously etched thereby forming upwardly convex projecting portions 10a having substantially flat upper surface portions 10b on the insulating film 10 of the pixel 100a, similarly to those shown in FIG. 15.

Then, a metal wire 16 and insulating films 11 are formed through steps similar to those of the first embodiment shown in FIGS. 16 and 17. Thereafter a resin layer 13 and a color filter layer 14 are formed similarly to those shown in FIG. 3.

In the manufacturing process for the solid-state imaging device according to the second embodiment, as hereinabove described, the lens 12 having a shape similar to that in the aforementioned first embodiment can be formed also through resist flowing. Thus, an effect of suppressing deterioration of the image quality can be attained similarly to the aforementioned first embodiment. In the resist flowing employed in the second embodiment, however, the shapes of the upwardly convex hemispheric resist films 21a are easily dispersed in formation of the resist films 21a to result in a possibility for dispersion of the shape of the lens 12. Therefore, reduction of the condensing efficiency resulting from dispersion of the shape of the lens 12 can be more suppressed in the first embodiment employing ion streaming.

The remaining effects of the second embodiment are similar to those of the aforementioned first embodiment.

### Third Embodiment

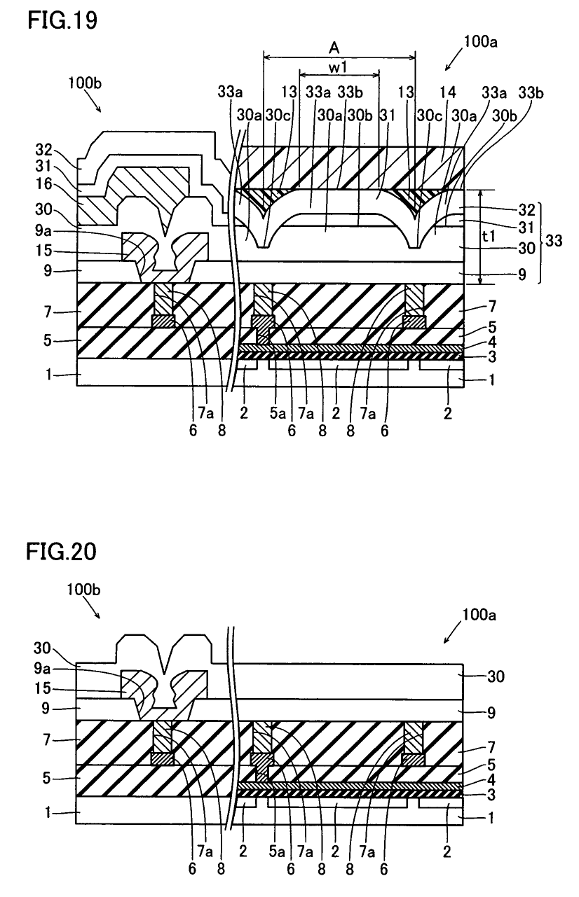

Referring to FIG. 19, a solid-state imaging device according to a third embodiment of the present invention is described with reference to a case of forming a lens 33 on a pixel 100a after forming two metal wires 15 and 16 on a wire forming region 100b, dissimilarly to the aforementioned first and second embodiments.

According to the third embodiment, an insulating film 30 of SiN having a thickness of about 500 nm is formed on an insulating film 9 in the pixel 100a, as shown in FIG. 19. The portion of the insulating film 30 located on the pixel 100a is an example of the “second insulating film” in the present invention. The insulating film 30 includes upwardly convex projecting portions 30a having substantially flat upper surface portions 30b. The plurality of projecting portions 30a are formed at prescribed intervals, while flat portions 30c are formed between adjacent ones of the projecting portions 30a. Still another insulating film 31 of SiN having a thickness of about 300 nm is formed on the upper surface portions 30b of the projecting portions 30a of the insulating film 30. The portion of the insulating film 31 located on the pixel 100a is an example of the “sixth insulating film” in the present invention. A further insulating film 32 of SiN having a thickness of about 500 nm is formed to cover the insulating films 30 and 31 while filling up the flat portions 30c between the adjacent projecting portions 30a. The portion of the insulating film 32 located on the pixel 100a is an example of the “sixth insulating film” in the present invention. According to the third embodiment, the insulating films 9, 30, 31 and 32 constitute the lens 33 for condensing light on photodetection areas 2. This lens 33 has a plurality of projecting portions 33a including substantially flat upper surface portions 33b having a width w1 of about 1.2 μm, and has a thickness t1 of about 1.7 μm. Further, the lens 33 has a width A of about 2.7 μm. In other words, the lens 33 of the solid-state imaging device according to the third embodiment has a shape similar to that of the lens 12 of the solid-state imaging device according to the first embodiment shown in FIG. 1.

In the pixel 100a, further, a resin layer 13 is formed on the lens 33 to fill up clearances between the adjacent projecting portions 33a. A color filter layer 14 is formed on the resin layer 13 to be in contact with the substantially flat upper surface portions 33b of the lens 33.

In the wire forming region 100b, on the other hand, an insulating film 30 of the same layer as the insulating film 30 of the pixel 100a is formed to cover the insulating film 9 and the metal wire 15. The portion of the insulating film 30 located on the wire forming region 100b is an example of the “first insulating film” in the present invention. The metal wire 16 is formed on a prescribed region of the insulating film 30. The metal wires 15 and 16 are connected with each other through a contact hole (not shown) provided in the insulating film 30. An insulating film 31 of the same layer as the insulating film 31 of the pixel 100a is formed to cover the insulating film 30 and the metal wire 16. The portion of the insulating film 31 located on the wire forming region 100b is an example of the “fifth insulating film” in the present invention. The insulating film 31 of the wire forming region 100b functions as a protective film for the metal wire 16. An insulating film 32 of the same layer as the insulating film 32 of the pixel 100a is formed on the insulating film 31. The portion of the insulating film 32 located on the wire forming region 100b is an example of the “fifth insulating film” in the present invention.

The remaining structure of the solid-state imaging device according to the third embodiment is similar to that of the solid-state imaging device according to the aforementioned first embodiment.

A manufacturing process for the solid-state imaging device according to the third embodiment is now described with reference to FIGS. 19 to 26.

First, the elements up to the metal wire 15 are formed through steps similar to those of the first embodiment shown in FIGS. 5 to 11.

As shown in FIG. 20, the insulating films 30 of SiN having the thickness of about 500 nm are formed by plasma CVD to cover the insulating film 9 provided on both of the pixel 100a and the wire forming region 100b and the metal wire 15.

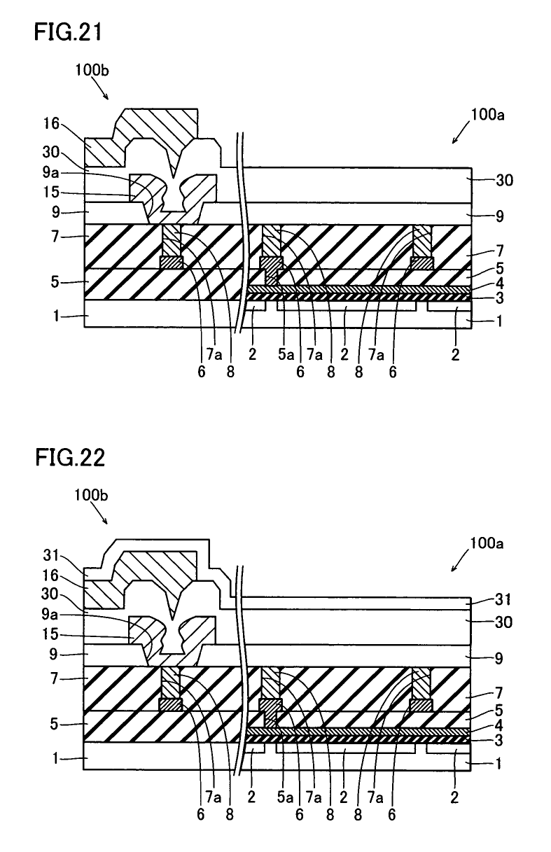

As shown in FIG. 21, a contact hole (not shown) reaching the upper surface of the metal wire 15 is formed in the insulating film 30 of the wire forming region 100b, and the metal wire 16 is thereafter formed on the prescribed region of the insulating film 30 to fill up the contact hole.

As shown in FIG. 22, the insulating films 31 of SiN having the thickness of about 300 nm are formed by plasma CVD to cover the insulating films 30 of the pixel 100a and the wire forming region 100b and the metal wire 16.

As shown in FIG. 23, resist films 41 are formed on prescribed regions of the insulating films 31 of the pixel 100a and the wire forming region 100b by photolithography.

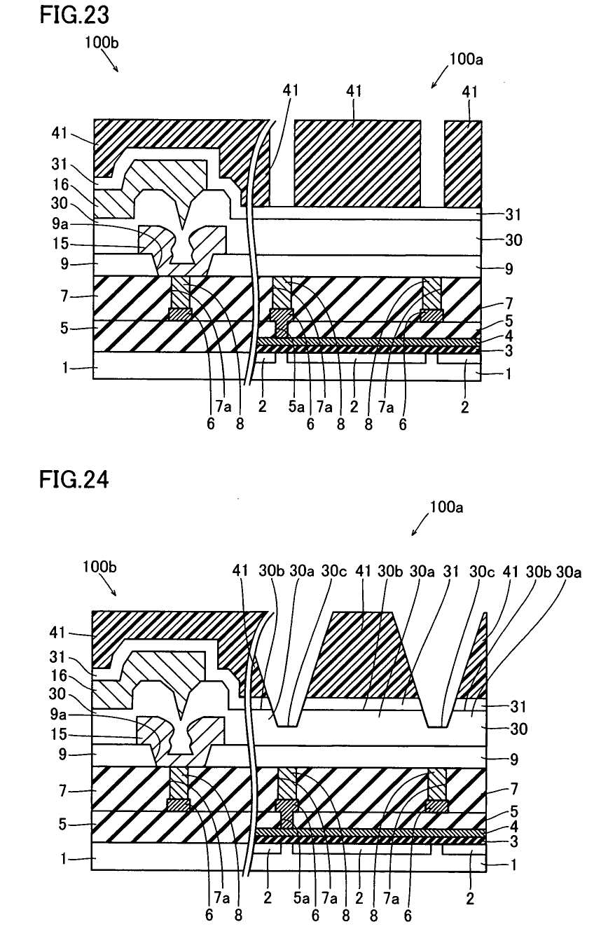

As shown in FIG. 24, the resist films 41 are employed as masks for dry-etching the insulating film 30 of the pixel 100a up to a prescribed depth. Thus, the upwardly convex projecting portions 30a having the substantially flat upper surface portions 30b are formed on the insulating film 30 of the pixel 100a. The plurality of projecting portions 30a are formed at the prescribed intervals, along with formation of the flat portions 30c between the adjacent projecting portions 30a. Thereafter the resist films 41 are removed.

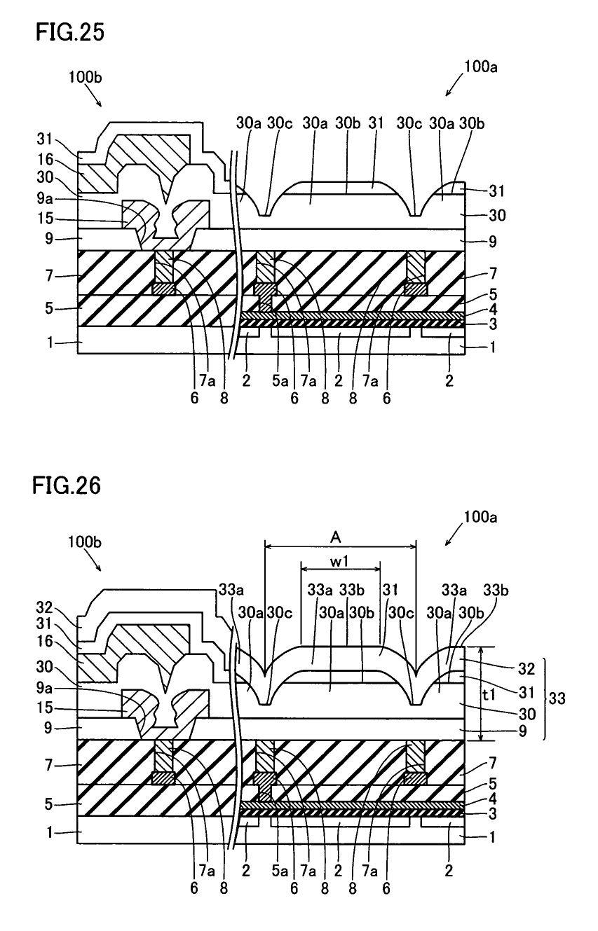

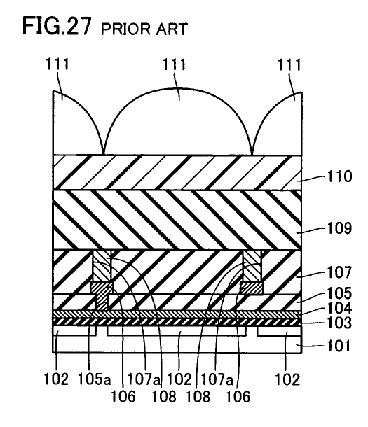

As shown in FIG. 25, ion streaming is performed for applying inert gas ions to the projecting portions 30a of the insulating film 30 and the insulating film 31 of the pixel 100a through an ion streaming etching system (by Tokyo Ohka Kogyo Co., Ltd.). Thus, corners of the projecting portions 30a of the insulating film 30 and the insulating film 31 are rounded, while scattered atoms and molecules are embedded in the flat portions 30c between the adjacent projecting portions 30a.

As shown in FIG. 26, the insulating films 32 of SiN having the thickness of about 500 nm are formed to cover the insulating films 30 and 31 of the pixel 100a and the wire forming region 100b while filling up the flat portions 30c between the adjacent projecting portions 30a of the insulating film 30 of the pixel 100a. Thus formed is the lens 33 having a four-layer structure consisting of the insulating films 9, 30, 31 and 32. This lens 33 is formed to include the plurality of projecting portions 33a, and to have the thickness t1 of about 1.7 μm. Further, the lens 33 is formed to have the width A of about 2.7 μm, and to include the substantially flat upper portions 33b having the width w1 of about 1.2 μm.

Thereafter the resin layer 13 is formed on the lens 33 of the pixel 100a to fill up the clearances between the adjacent projecting portions 33a, as shown in FIG. 19. The color filter layer 14 is formed on the resin layer 13 to be in contact with the substantially flat upper surface portions 33b of the lens 33. Thus, the solid-state imaging device according to the third embodiment is formed.

In the manufacturing process for the solid-state imaging device according to the third embodiment, as hereinabove described, the lens 33 can be shaped similarly to the lens 12 of the aforementioned first embodiment also when the same is formed on the pixel 100a after the metal wire 16 is formed on the wire forming region 100b. Therefore, an effect of suppressing deterioration of the image quality can be attained similarly to the aforementioned first embodiment. According to the third embodiment, however, the insulating film 32 for filling up the flat portions 30c between the adjacent projecting portions 30a of the insulating film 30 constituting the lens 33 must be formed after formation of the insulating film 31 functioning as the protective film for the metal wire 16, and hence the number of the steps of the manufacturing process is increased as compared with the first embodiment.

The remaining effects of the third embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the ratio (w/t) of the width w of the substantially flat upper surface portions of the lens to the thickness t of the lens is set to about 0.71 in each of the aforementioned first to third embodiments, the present invention is not restricted to this but a similar effect can be attained so far as the ratio w (width of substantially flat upper surface portion)/t (thickness of lens) is not more than 0.86.

While the width of the lens (pixel size) is set to about 2.7 μm in each of the aforementioned first to third embodiments, the present invention is not restricted to this but the pixel size may alternatively be set to a value, other than 2.7 μm, of not more than 3 μm. When the pixel size is set to 3 μm, the ratio w (width of substantially flat upper surface portion)/t (thickness of lens) is preferably set to not more than 0.65.

While the lens consists of three or four insulating films in each of the aforementioned first to third embodiments, the present invention is not restricted to this but the lens may alternatively consist of a single insulating film or at least five insulating films.

1. A solid-state imaging device comprising:
a substrate provided with a photodetection area;
a color filter layer formed above said photodetection area; and
a lens formed between said substrate and said color filter layer for condensing light on said photodetection area, wherein
said lens has a substantially flat upper surface portion, and the ratio (w/t) of the width w of said substantially flat upper surface portion of said lens to the thickness t of said lens is not more than about 0.86.

2. The solid-state imaging device according to claim 1, wherein
the width of said lens is not more than about 2.7 μm.

3. The solid-state imaging device according to claim 1, wherein
the ratio (w/t) of the width w of said substantially flat upper surface portion of said lens to the thickness t of said lens is not more than about 0.65, and
the width of said lens is not more than about 3 μm.

4. The solid-state imaging device according to claim 1, wherein
said lens includes a plurality of layers.

5. The solid-state imaging device according to claim 1, further comprising:
a first metal wire formed on a region other than a region of said substrate provided with said photodetection area, and
a second metal wire formed on said first metal wire through a first insulating film, wherein
said lens includes a second insulating film consisting of the same layer as at least said first insulating film.

6. The solid-state imaging device according to claim 5, wherein
said first metal wire has a function of supplying an external signal to a pixel, and said second metal wire has a function of supplying said external signal to said first metal wire.

7. The solid-state imaging device according to claim 5, wherein
said second insulating film constituting said lens has an upwardly convex projecting portion.

8. The solid-state imaging device according to claim 5, wherein
said first insulating film and said second insulating film consist of SiN films.

9. The solid-state imaging device according to claim 5, further comprising:
a third insulating film arranged downward beyond the upper end of said first metal wire, and
a fourth insulating film, formed under said second insulating film constituting said lens, consisting of the same layer as said third insulating film and constituting
said lens along with said second insulating film, wherein said fourth insulating film is arranged downward beyond the upper end of said first metal wire.

10. The solid-state imaging device according to claim 9, wherein
said fourth insulating film constituting said lens has a substantially flat surface, and said second insulating film is formed on said substantially flat surface of said fourth insulating film.

11. The solid-state imaging device according to claim 9, wherein
said third insulating film and said fourth insulating film consist of SiN films.

12. The solid-state imaging device according to claim 9, wherein
said second insulating film and said fourth insulating film constituting said lens consist of materials having substantially identical refractive indices.

13. The solid-state imaging device according to claim 9, wherein
at least either said second insulating film or said fourth insulating film consists of a material containing hydrogen.

14. The solid-state imaging device according to claim 13, wherein
both of said second insulating film and said fourth insulating film consist of materials containing hydrogen.

15. The solid-state imaging device according to claim 5, further comprising:
a fifth insulating film formed on said second metal wire, and
a sixth insulating film, formed on said second insulating film constituting said lens, consisting of the same layer as said fifth insulating film and constituting said lens along with said second insulating film.

16. The solid-state imaging device according to claim 15, wherein
said second insulating film constituting said lens includes a plurality of upwardly convex projecting portions formed at a prescribed interval, and
said sixth insulating film constituting said lens is formed to fill up a flat portion between adjacent said projecting portions of said second insulating film.

17. The solid-state imaging device according to claim 16, wherein
a region of said sixth insulating film constituting said lens corresponding to said flat portion between adjacent said projecting portions of said second insulating film is formed to include no flat portion.

18. The solid-state imaging device according to claim 15, wherein
said sixth insulating film constituting said lens is formed to be upwardly convex, and has a substantially flat upper surface portion.

19. The solid-state imaging device according to claim 15, wherein
said fifth insulating film and said sixth insulating film consist of SiN films.

20. The solid-state imaging device according to claim 15, wherein
said second insulating film and said sixth insulating film constituting said lens consist of materials having substantially identical refractive indices.
